(19) United States
(12) Patent Application Publication
(10) Pub. No.: US 2025/0289221 A1
(43) Pub. Date: Sep. 18, 2025

(54) Liquid Discharge Head And Liquid Discharge Device

(71) Applicant: SEIKO EPSON CORPORATION, Tokyo (JP)

(72) Inventors: Nobuo OZAWA, Shiojiri (JP); Shunsuke YOSHIDA, Matsumoto (JP); Toshihiro SHIMIZU, Fujimi (JP)

(21) Appl. No.: 19/076,159

(22) Filed: Mar. 11, 2025

(30) Foreign Application Priority Data
Mar. 12, 2024 (JP) 2024-037713

(51) Int. Cl. B41J 2/14; H10N 30/88

(52) U.S. Cl. CPC B41J 2/14233; H10N 30/883; B41J 2002/14241; B41J 2202/03

(57) ABSTRACT

a protective layer provided on the other side with respect to the piezoelectric body in a boundary region, which is a boundary between a first region and a second region in the extending direction when the first region is set to a region where the piezoelectric body overlaps the second electrode in the lamination direction and the second region is set to a region where the piezoelectric body is present and the second electrode is not present in the lamination direction, in which the protective layer includes a first inorganic film made of an inorganic material, and a second inorganic film made of an inorganic material different from the first inorganic film, and the first region overlaps the pressure chamber in the lamination direction.

The present application is based on, and claims priority from JP Application Serial Number 2024-037713, filed Mar. 12, 2024, the disclosure of which is hereby incorporated by reference herein in its entirety.

### BACKGROUND

### 1. Technical Field

The present disclosure relates to a liquid discharge head and a liquid discharge device.

### 2. Related Art

JP-A-2016-135611 discloses a liquid ejecting head having a protective film covering a region including a boundary between a region where a piezoelectric layer is not covered with an upper electrode and a region where the piezoelectric layer is covered with the upper electrode.

When moisture is mixed in a crack generated in the piezoelectric body in the vicinity of the end portion of the electrode laminated on the piezoelectric body, there is a case where two electrodes laminated to interpose the piezoelectric body are short-circuited and burning occurs in the piezoelectric body. Therefore, a technique is desired for reducing the possibility that the burning occurs in the piezoelectric body in the vicinity of the end portion of the electrode laminated on the piezoelectric body.

### SUMMARY

According to a first aspect of the present disclosure, there is provided a liquid discharge head. The liquid discharge head includes a piezoelectric body; a pressure chamber substrate provided with a plurality of pressure chambers arranged in an arrangement direction, which is a direction intersecting an extending direction of the pressure chamber, the pressure chamber being configured to apply pressure to a liquid stored inside when the piezoelectric body is driven; a first electrode provided on one side of a lamination direction, which is a direction intersecting the extending direction and the arrangement direction, with respect to the piezoelectric body; a second electrode provided on another side of the lamination direction, which is a side opposite to the one side, with respect to the piezoelectric body; and a protective layer provided on the other side with respect to the piezoelectric body in a boundary region, which is a boundary between a first region and a second region, in the extending direction when the first region is set to a region where the piezoelectric body overlaps the second electrode in the lamination direction and the second region is set to a region where the piezoelectric body is present and the second electrode is not present in the lamination direction, in which the protective layer includes a first inorganic film made of an inorganic material, and a second inorganic film made of an inorganic material different from the first inorganic film, and the first region overlaps the pressure chamber in the lamination direction.

According to a second aspect of the present disclosure, there is provided a liquid discharge device. The liquid discharge device includes the liquid discharge head of the first aspect, and a control section that controls a discharge operation of discharging a liquid from the liquid discharge head.

### BRIEF DESCRIPTION OF THE DRAWINGS

FIG. 1 is an explanatory diagram illustrating a schematic configuration of a liquid discharge device according to a first embodiment.

FIG. 2 is an exploded perspective view illustrating a configuration of a liquid discharge head.

FIG. 3 is an explanatory diagram illustrating the configuration of the liquid discharge head in a plan view.

FIG. 4 is a cross-sectional view illustrating a position IV-IV in FIG. 3.

FIG. 5 is an enlarged explanatory diagram illustrating a partial range of FIG. 3.

FIG. 6 is a cross-sectional view illustrating a position VI-VI in FIG. 5.

FIG. 7 is an enlarged cross-sectional view of a vicinity of a protective layer.

FIG. 8 is an enlarged cross-sectional view of a vicinity of a protective layer according to a second embodiment.

FIG. 9 is an enlarged cross-sectional view of a vicinity of a protective layer according to a third embodiment.

FIG. 10 is an enlarged cross-sectional view of a vicinity of a protective layer according to a fourth embodiment.

FIG. 11 is an enlarged cross-sectional view of a vicinity of a protective layer according to a fifth embodiment.

FIG. 12 is an enlarged cross-sectional view of a vicinity of a protective layer according to another embodiment.

### DESCRIPTION OF EMBODIMENTS

### A. First Embodiment

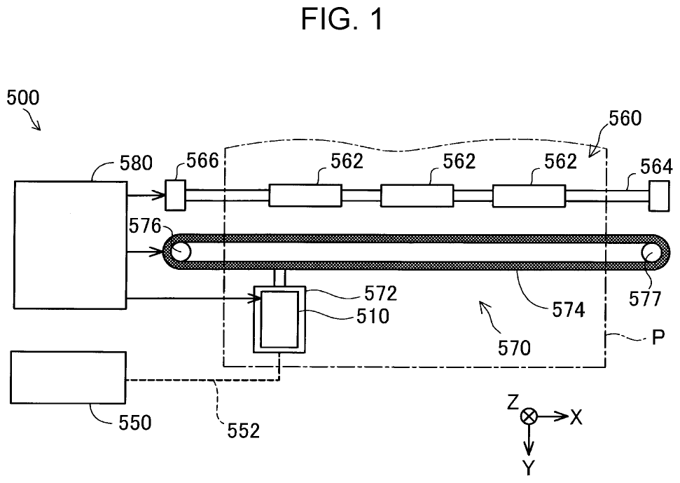

FIG. 1 is an explanatory diagram illustrating a schematic configuration of a liquid discharge device 500 according to a first embodiment. In the present embodiment, the liquid discharge device 500 is an ink jet printer that discharges ink as an example of a liquid onto printing paper P to form an image. The liquid discharge device 500 may use any kind of medium, such as a resin film or a cloth, as a target on which ink is to be discharged, instead of the printing paper P. X, Y, and Z illustrated in FIG. 1 and each drawing subsequent to FIG. 1 represent three spatial axes orthogonal to each other. In the present specification, directions along the axes are also referred to as an X-axis direction, a Y-axis direction, and a Z-axis direction. In specifying the direction, a positive direction is “+” and a negative direction is “−” so that positive and negative signs are used together in the direction notation, and description will be performed while a direction to which an arrow faces in each drawing is the +direction and an opposite direction thereof is the −direction. In the present embodiment, the Z-axis direction coincides with a vertical direction, the +Z direction indicates vertically downward, and the −Z direction indicates vertically upward. Further, when the positive direction and the negative direction are not limited, the three X, Y, and Z will be described as the X axis, the Y axis, and the Z axis.

The liquid discharge device 500 includes a liquid discharge head 510, an ink tank 550, a transport mechanism 560, a movement mechanism 570, and a control section 580. The liquid discharge head 510 is formed with a plurality of nozzles, discharges inks of a total of four colors, for example, black, cyan, magenta, and yellow in the +Z direction to form an image on a printing paper P. The liquid discharge head 510 is mounted on the carriage 572 and reciprocates in a main scanning direction with the movement of the carriage 572. In the present embodiment, the main scanning directions are the +X direction and the −X direction. The liquid discharge head 510 may further discharge ink of a random color such as light cyan, light magenta, or clear white, in addition to the four colors.

The ink tank 550 accommodates the ink to be discharged to the liquid discharge head 510. The ink tank 550 is coupled to the liquid discharge head 510 by a resin tube 552. The ink in the ink tank 550 is supplied to the liquid discharge head 510 via the tube 552. Instead of the ink tank 550, a bag-shaped liquid pack formed of a flexible film may be provided.

The transport mechanism 560 transports the printing paper P in a sub-scanning direction. The sub-scanning direction is a direction that intersects the X-axis direction, which is a main scanning direction, and is the +Y direction and the −Y direction in the present embodiment. The transport mechanism 560 includes a transport rod 564, on which three transport rollers 562 are mounted, and a transport motor 566 for rotatably driving the transport rod 564. When the transport motor 566 rotatably drives the transport rod 564, the printing paper P is transported in the +Y direction, which is the sub-scanning direction. The number of the transport rollers 562 is not limited to three and may be a random number. Further, a configuration, in which a plurality of transport mechanisms 560 are provided, may be provided.

The movement mechanism 570 includes a carriage 572, a transport belt 574, a movement motor 576, and a pulley 577. The carriage 572 mounts the liquid discharge head 510 in a state where the ink can be discharged. The carriage 572 is fixed to the transport belt 574. The transport belt 574 is bridged between the movement motor 576 and the pulley 577. When the movement motor 576 is rotatably driven, the transport belt 574 reciprocates in the main scanning direction. As a result, the carriage 572 fixed to the transport belt 574 also reciprocates in the main scanning direction.

The control section 580 is configured as a microcomputer including a CPU and a storage section. The storage section is, for example, a non-volatile memory such as an EEPROM that can be erased by an electric signal, a non-volatile memory such as a One-Time-PROM and an EPROM that can be erased by ultraviolet rays, or a non-volatile memory such as a PROM that cannot be erased. The storage section stores various programs for realizing functions provided in the present embodiment. The CPU oversees the control of each section of the liquid discharge device 500 by developing and executing a program stored in the storage section. The control section 580 controls the reciprocating operation of the carriage 572 along the main scanning direction, the transport operation of the printing paper P along the sub-scanning direction, and the discharge operation of discharging the liquid from the liquid discharge head 510.

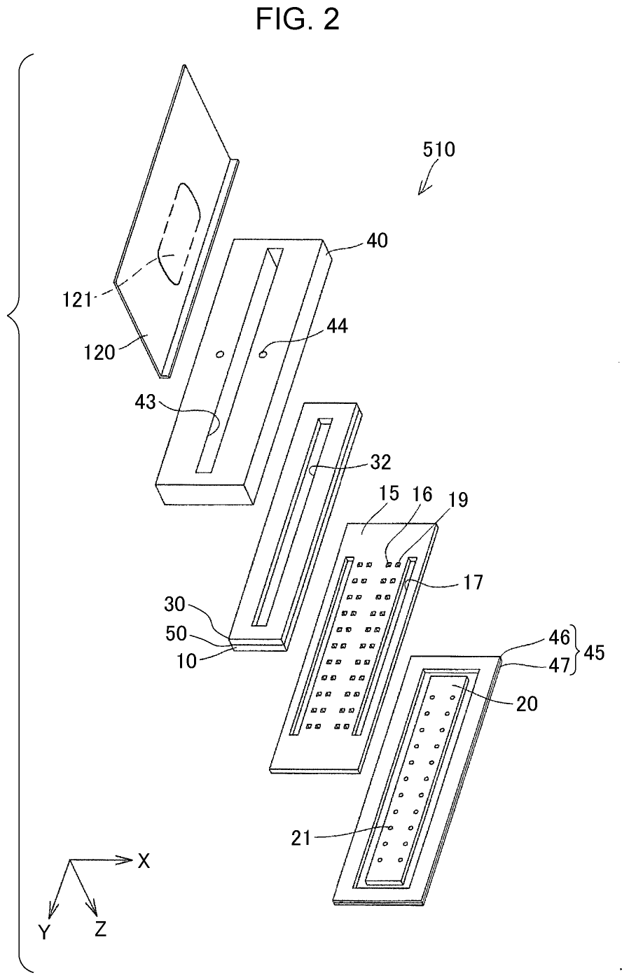

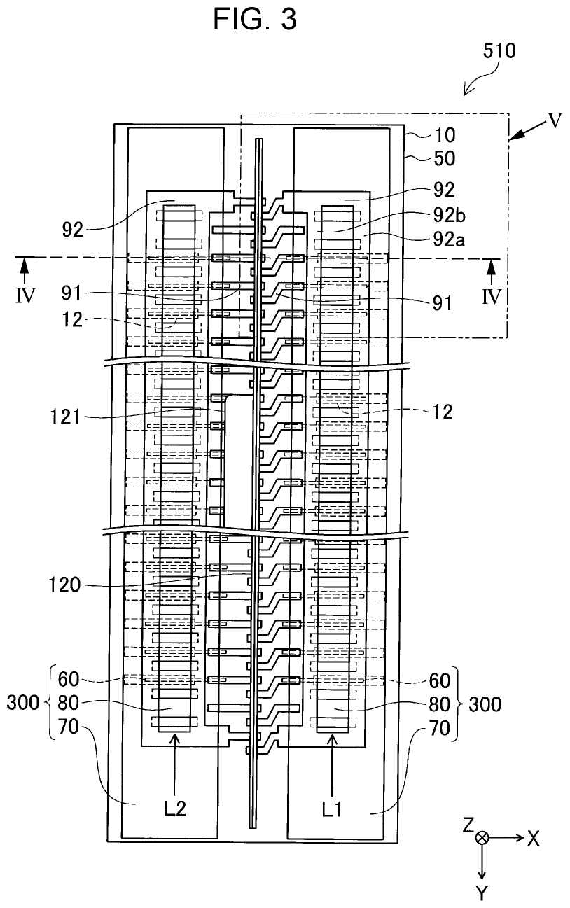

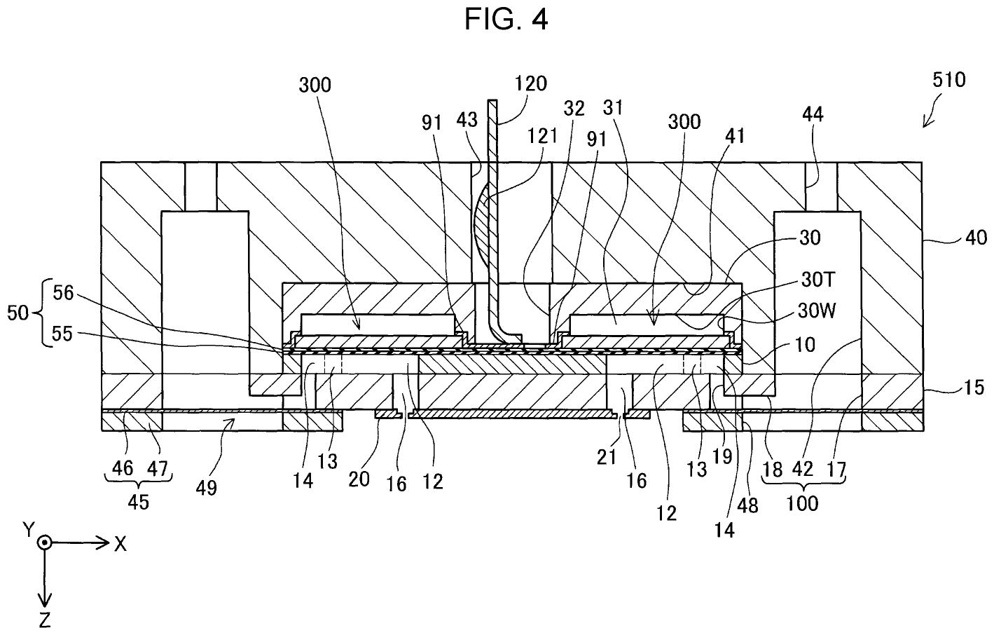

A detailed configuration of the liquid discharge head 510 will be described with reference to FIGS. 2 to 4. FIG. 2 is an exploded perspective view illustrating the configuration of the liquid discharge head 510. FIG. 3 is an explanatory diagram illustrating the configuration of the liquid discharge head 510 in a plan view. In the present disclosure, the “plan view” means a state in which an object is viewed along a lamination direction to be described later. FIG. 3 illustrates the configuration around a pressure chamber substrate 10 and a vibration plate 50 in the liquid discharge head 510. In order to facilitate understanding of the technique, a protective layer 82, a sealing substrate 30, a case member 40, and the like are not illustrated. FIG. 4 is a cross-sectional view illustrating an IV-IV position of FIG. 3.

The liquid discharge head 510 includes a pressure chamber substrate 10, a communication plate 15, a nozzle plate 20, a compliance substrate 45, a vibration plate 50, a sealing substrate 30, a case member 40, a wiring substrate 120, which are illustrated in FIG. 2, and a piezoelectric element 300 illustrated in FIG. 3. The liquid discharge head 510 is configured by laminating these laminated members. In the present disclosure, a direction in which the laminated members forming the liquid discharge head 510 are laminated is also referred to as a “lamination direction”. In the present embodiment, the lamination direction coincides with the Z-axis direction. In the present disclosure, the +Z direction side with respect to a predetermined reference position is also referred to as “one side of the lamination direction” or “lower side”, and the −Z direction side with respect to a predetermined reference position is also referred to as “the other side of the lamination direction” or “upper side”.

The pressure chamber substrate 10 is formed by using, for example, a silicon substrate, a glass substrate, an SOI substrate, various ceramic substrates, and the like. As illustrated in FIG. 3, a plurality of pressure chambers 12 are provided on the pressure chamber substrate 10. An ink flow path provided on the pressure chamber substrate 10, such as the pressure chamber 12, is formed by anisotropically etching the pressure chamber substrate 10 from the surface on the +Z direction side. The pressure chamber 12 is provided to extend along the X-axis direction. Specifically, the pressure chamber 12 is formed in a substantially rectangular shape in which the length in the X-axis direction is longer than the length in the Y-axis direction in a plan view. The shape of the pressure chamber 12 is not limited to the rectangular shape, and may be a parallelogram shape, a polygonal shape, an oval shape, or the like. The oval shape means a shape in which both end portions in a longitudinal direction are semicircular based on a rectangular shape, and includes a rounded rectangular shape, an elliptical shape, an egg shape, and the like. In the present disclosure, the X-axis direction is also referred to as an “extending direction”.

As illustrated in FIG. 3, the plurality of pressure chambers 12 are arranged along a direction intersecting the extending direction on the pressure chamber substrate 10. In plan view of the liquid discharge head 510 along the lamination direction, a direction in which the plurality of pressure chambers 12 are arranged is also referred to as an “arrangement direction”. That is, the arrangement direction is a direction intersecting the extending direction and the lamination direction. In the present embodiment, the plurality of pressure chambers 12 are arranged in two rows parallel to each other with the Y-axis direction as the arrangement direction. In the example of FIG. 3, the pressure chamber substrate 10 is provided with two pressure chamber rows, that is, a first pressure chamber row L1 having a first arrangement direction parallel to the Y-axis direction and a second pressure chamber row L2 having a second arrangement direction parallel to the Y-axis direction. The first pressure chamber row L1 and the second pressure chamber row L2 are disposed on both sides with the wiring substrate 120 interposed therebetween. Specifically, the second pressure chamber row L2 is disposed on the opposite side of the first pressure chamber row L1 with the wiring substrate 120 interposed therebetween in the X-axis direction, which is the extending direction. In the example of FIG. 3, the second pressure chamber row L2 is disposed in the −X direction with the wiring substrate 120 interposed between the second pressure chamber row L2 and the first pressure chamber row L1. In the plurality of pressure chambers 12, all the pressure chambers 12 do not necessarily have to be arranged in a straight line. For example, the plurality of pressure chambers 12 may be arranged along the Y-axis direction according to so-called staggered arrangement in which every other pressure chamber 12 is alternately disposed in the intersection direction.

As illustrated in FIG. 2, the communication plate 15, the nozzle plate 20, and the compliance substrate 45 are laminated on the +Z direction side of the pressure chamber substrate 10. The communication plate 15 is, for example, a flat plate member using a silicon substrate, a glass substrate, an SOI substrate, various ceramic substrates, a metal substrate, or the like. Examples of the metal substrate include a stainless steel substrate or the like. The communication plate 15 is provided with a nozzle communication path 16, a first manifold portion 17, a second manifold portion 18 illustrated in FIG. 4, and a supply communication path 19. It is preferable that the communication plate 15 is formed by using a material having a thermal expansion coefficient substantially the same as a thermal expansion coefficient of the pressure chamber substrate 10. As a result, when the temperatures of the pressure chamber substrate 10 and the communication plate 15 change, the warping of the pressure chamber substrate 10 and the communication plate 15 due to a difference in the thermal expansion coefficient can be suppressed.

As illustrated in FIG. 4, the nozzle communication path 16 is a flow path that communicates the pressure chamber 12 and a nozzle 21. The first manifold portion 17 and the second manifold portion 18 function as a part of a manifold 100 which is a common liquid chamber in which a plurality of pressure chambers 12 communicate with each other. The first manifold portion 17 is provided to penetrate the communication plate 15 in the Z-axis direction. Further, as illustrated in FIG. 4, the second manifold portion 18 is provided on a surface of the communication plate 15 on the +Z direction side without penetrating the communication plate 15 in the Z-axis direction.

As illustrated in FIG. 4, the supply communication path 19 is a flow path coupled to a pressure chamber supply path 14 provided on the pressure chamber substrate 10. The pressure chamber supply path 14 is a flow path coupled to one end portion of the pressure chamber 12 in the X-axis direction via a throttle portion 13. The throttle portion 13 is a flow path provided between the pressure chamber 12 and the pressure chamber supply path 14. The throttle portion 13 is a flow path in which an inner wall protrudes from the pressure chamber 12 and the pressure chamber supply path 14 and which is formed narrower than the pressure chamber 12 and the pressure chamber supply path 14. Thereby, the throttle portion 13 is set such that the flow path resistance is higher than those of the pressure chamber 12 and the pressure chamber supply path 14. With the configuration, even when pressure is applied to the pressure chamber 12 by the piezoelectric element 300 when the ink is discharged, the ink in the pressure chamber 12 can be suppressed or prevented from flowing back to the pressure chamber supply path 14. A plurality of supply communication paths 19 are arranged along the Y-axis direction, that is, the arrangement direction, and are individually provided for the respective pressure chambers 12. The supply communication path 19 and the pressure chamber supply path 14 communicates the second manifold portion 18 with each pressure chamber 12, and supplies the ink in the manifold 100 to each pressure chamber 12.

The nozzle plate 20 is provided on a side opposite to the pressure chamber substrate 10, that is, on a surface of the communication plate 15 on the +Z direction side with the communication plate 15 interposed therebetween. The material of the nozzle plate 20 is not particularly limited, and, for example, a silicon substrate, a glass substrate, an SOI substrate, various ceramic substrates, and a metal substrate can be used. Examples of the metal substrate include a stainless steel substrate or the like. As the material of the nozzle plate 20, an organic material, such as a polyimide resin, can also be used. However, it is preferable that the nozzle plate 20 uses a material substantially the same as the thermal expansion coefficient of the communication plate 15. As a result, when the temperatures of the nozzle plate 20 and the communication plate 15 change, the warping of the nozzle plate 20 and the communication plate 15 due to the difference in the thermal expansion coefficient can be suppressed.

A plurality of nozzles 21 are formed on the nozzle plate 20. Each nozzle 21 communicates with each pressure chamber 12 via the nozzle communication path 16. As illustrated in FIG. 2, the plurality of nozzles 21 are arranged along the arrangement direction of the pressure chamber 12, that is, the Y-axis direction. The nozzle plate 20 is provided with two nozzle rows in which the plurality of nozzles 21 are arranged in a row. The two nozzle rows respectively correspond to the first pressure chamber row L1 and the second pressure chamber row L2.

As illustrated in FIG. 4, the compliance substrate 45 is provided together with the nozzle plate 20 on the side opposite to the pressure chamber substrate 10 with the communication plate 15 interposed therebetween, that is, on a surface of the communication plate 15 on the +Z direction side. The compliance substrate 45 is provided around the nozzle plate 20 and covers openings of the first manifold portion 17 and the second manifold portion 18 provided in the communication plate 15. The compliance substrate 45 includes, for example, a sealing film 46 made of a flexible thin film and a fixed substrate 47 made of a hard material such as a metal. As illustrated in FIG. 4, a region of the fixed substrate 47 facing the manifold 100 is completely removed in a thickness direction, and thus an opening portion 48 is defined. Therefore, one surface of the manifold 100 is a compliance portion 49 sealed only by the sealing film 46.

As illustrated in FIG. 4, the vibration plate 50 and the piezoelectric element 300 are laminated on a side opposite to the communication plate 15 or the like, that is, on a surface of the pressure chamber substrate 10 on the −Z direction side with the pressure chamber substrate 10 interposed therebetween. The piezoelectric element 300 bends and deforms the vibration plate 50 to cause a pressure change in the ink in the pressure chamber 12. In FIG. 4, illustration of the piezoelectric element 300 is simplified.

The vibration plate 50 is provided between the piezoelectric element 300 and the pressure chamber substrate 10. The vibration plate 50 is provided at a position closer to the pressure chamber substrate 10 side than the piezoelectric element 300, and includes an elastic film 55 containing silicon oxide (SiO₂) and an insulator film 56 that is provided on the elastic film 55 and contains a zirconium oxide film (ZrO₂). The elastic film 55 constitutes a surface of the flow path, such as the pressure chamber 12, on the −Z direction side. In addition, the vibration plate 50 may be composed of, for example, either the elastic film 55 or the insulator film 56, and may further include another film other than the elastic film 55 and the insulator film 56. Examples of the material of the other film include silicon, silicon nitride, and the like.

As illustrated in FIG. 2, the sealing substrate 30 having substantially the same size as the pressure chamber substrate 10 in a plan view is further bonded to the surface of the pressure chamber substrate 10 on the −Z direction side by an adhesive or the like. As illustrated in FIG. 4, the sealing substrate 30 includes a ceiling portion 30T, a wall portion 30W, a holding portion 31, and a through hole 32. The holding portion 31 is a space defined by the ceiling portion 30T and the wall portion 30W, and protects an active portion of the piezoelectric element 300 by accommodating the piezoelectric element 300. In the present embodiment, the holding portions 31 are provided for each row of the piezoelectric elements 300. More specifically, two holding portions 31 corresponding to the first pressure chamber row L1 and the second pressure chamber row L2 are formed to be adjacent to each other. The through hole 32 penetrates the sealing substrate 30 along the Z-axis direction. The through hole 32 is disposed between the two holding portions 31 in plan view, and is formed in a long rectangular shape along the Y-axis direction.

As illustrated in FIG. 4, the case member 40 is fixed on the sealing substrate 30. The case member 40 forms the manifold 100 that communicates with the plurality of pressure chambers 12, together with the communication plate 15. The case member 40 has substantially the same outer shape as the communication plate 15 in plan view, and is bonded to cover the sealing substrate 30 and the communication plate 15.

The case member 40 has an accommodation section 41, a supply port 44, a third manifold portion 42, and a coupling port 43. The accommodation section 41 is a space having a depth in which the pressure chamber substrate 10, the vibration plate 50, and the sealing substrate 30 can be accommodated. The third manifold portion 42 is a space provided in the vicinity of both ends of the accommodation section 41 in the X-axis direction in the case member 40. The manifold 100 is formed by coupling the third manifold portion 42 to the first manifold portion 17 and the second manifold portion 18 provided in the communication plate 15. The manifold 100 has a long shape in the Y-axis direction. The supply port 44 communicates with the manifold 100 to supply ink to each manifold 100. The coupling port 43 is a through hole that communicates with the through hole 32 of the sealing substrate 30, and the wiring substrate 120 is inserted thereto.

In the liquid discharge head 510, the ink supplied from the ink tank 550 illustrated in FIG. 1 is taken from the supply port 44 illustrated in FIG. 4, and an internal flow path from the manifold 100 to the nozzle 21 is filled with ink. Thereafter, a voltage based on the drive signal is applied to each of the piezoelectric elements 300 corresponding to the plurality of pressure chambers 12. Thereby, the vibration plate 50 bends and deforms together with the piezoelectric element 300, and thus the volume of each pressure chamber 12 changes and the internal pressure increases. Therefore, ink droplets are discharged from each nozzle 21.

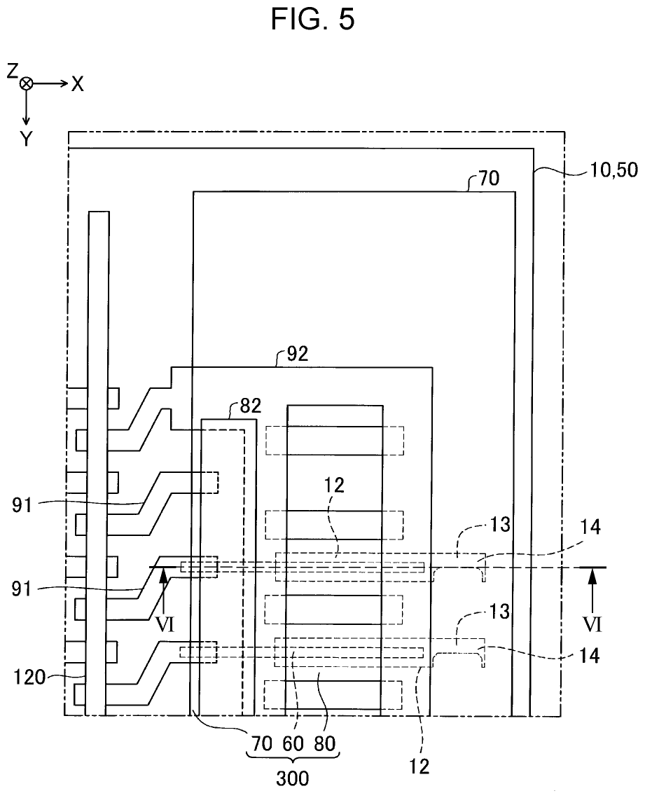

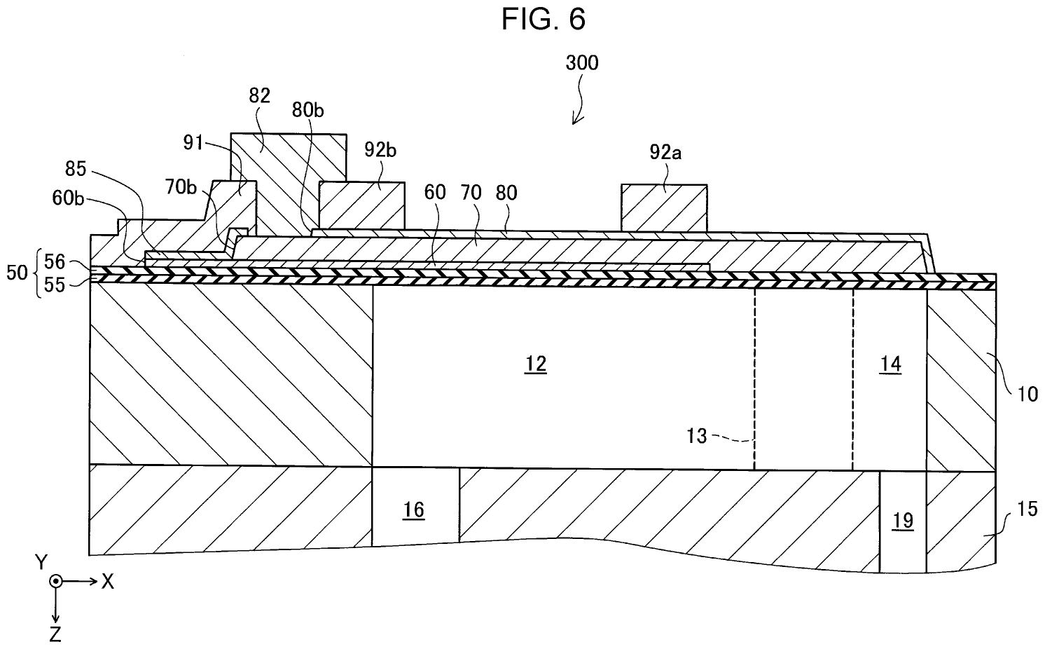

The configuration of the piezoelectric element 300 will be described with reference to FIGS. 3 and 4 and FIGS. 5 and 6 as appropriate. FIG. 5 is an enlarged explanatory diagram illustrating a partial range V of FIG. 3. FIG. 6 is a cross-sectional view illustrating a VI-VI position of FIG. 5.

As illustrated in FIG. 6, the piezoelectric element 300 has a first electrode 60, a piezoelectric body 70, and a second electrode 80. The first electrode 60, the piezoelectric body 70, and the second electrode 80 are laminated in this order in the −Z direction of the lamination direction. The piezoelectric body 70 is provided between the first electrode 60 and the second electrode 80 in the lamination direction. The first electrode 60 is provided on the +Z direction side of the piezoelectric body 70, and the second electrode 80 is provided on the −Z direction side of the piezoelectric body 70.

As illustrated in FIG. 5, the first electrode 60 and the second electrode 80 are electrically coupled to the wiring substrate 120 illustrated in FIG. 4 via the drive wiring. The drive wiring includes a first drive wiring 91 that electrically couples the wiring substrate 120 and the first electrode 60, and a second drive wiring 92 that electrically couples the wiring substrate 120 and the second electrode 80. The first electrode 60 and the second electrode 80 apply a voltage corresponding to the drive signal to the piezoelectric body 70. The drive voltage is a voltage applied to the piezoelectric element 300 from the first electrode 60 and the second electrode 80 in order to drive the piezoelectric element 300 by the control section 580. When a voltage is applied between the first electrode 60 and the second electrode 80, a part, at which piezoelectric distortion occurs in the piezoelectric body 70, in the piezoelectric element 300 is also referred to as an active portion.

A different drive voltage is applied to the first electrode 60 according to a discharge amount of ink, and a predetermined reference voltage is applied to the second electrode 80 regardless of the discharge amount of ink. When a voltage difference is generated between the first electrode 60 and the second electrode 80 by applying the drive voltage and the reference voltage, the piezoelectric body 70 of the piezoelectric element 300 is deformed. Due to the deformation of the piezoelectric body 70, the vibration plate 50 is deformed or vibrated, so that the volume of the pressure chamber 12 changes. Due to the change in the volume of the pressure chamber 12, pressure is applied to the ink accommodated in the pressure chamber 12, and the ink is discharged from the nozzle 21 via the nozzle communication path 16.

In the present embodiment, the first electrode 60 is an individual electrode individually provided for the plurality of pressure chambers 12. As illustrated in FIG. 6, the first electrode 60 is a lower electrode provided on the opposite side to the second electrode 80 with the piezoelectric body 70 interposed therebetween, that is, on the lower side of the piezoelectric body 70. The thickness of the first electrode 60 is formed to be, for example, approximately 80 nanometers. For example, the first electrode 60 is formed of a conductive material including a metal, such as platinum (Pt), iridium (Ir), gold (Au), titanium (Ti), and a conductive metal oxide such as indium tin oxide abbreviated as ITO. The first electrode 60 may be formed by laminating a plurality of materials such as platinum (Pt), iridium (Ir), gold (Au), and titanium (Ti). In the present embodiment, platinum (Pt) is used as the first electrode 60.

As illustrated in FIG. 3, the piezoelectric body 70 has a predetermined width in the X-axis direction, and has a long rectangular shape along the arrangement direction of the pressure chambers 12, that is, the Y-axis direction. The thickness of the piezoelectric body 70 is formed, for example, from approximately 1000 nanometers to 4000 nanometers. Examples of the piezoelectric body 70 include a crystal film having a perovskite structure formed on the first electrode 60 and made of a ferroelectric ceramic material exhibiting an electromechanical conversion action, that is, a so-called perovskite type crystal. As the material of the piezoelectric body 70, for example, a ferroelectric piezoelectric material such as lead zirconate titanate (PZT) or a material to which a metal oxide, such as niobium oxide, nickel oxide, or magnesium oxide, is added can be used. Specifically, lead titanate (PbTiO₃), lead zirconate titanate (Pb(Zr,Ti)O₃), lead zirconate (PbZrO₃), lead lanthanum titanate ((Pb,La), TiO₃), lead lanthanum zirconate titanate ((Pb,La)(Zr,Ti)O₃) or lead magnesium niobate zirconium titanate (Pb(Zr,Ti)(Mg,Nb)O₃), or the like, can be used. In the present embodiment, lead zirconate titanate (PZT) is used as the piezoelectric body 70.

The material of the piezoelectric body 70 is not limited to the lead-based piezoelectric material containing lead, and a lead-free piezoelectric material containing no lead can also be used. Examples of lead-free piezoelectric materials include bismuth iron acid ((BiFeO₃), abbreviated as “BFO”), barium titanate ((BaTIO₃), abbreviated as “BT”), potassium sodium niobate ((K, Na) (NbO₃), abbreviated as “KNN”), potassium sodium lithium niobate ((K,Na,Li)(NbO₃)), potassium sodium lithium niobate tantalate ((K,Na,Li)(Nb,Ta)O₃), bismuth potassium titanate ((Bi_{1/2}K_{1/2})TiO₃, abbreviated as “BKT”), bismuth sodium titanate ((Bi_{1/2}Na_{1/2})TiO₃, abbreviated as “BNT”), bismuth manganate (BimnO₃, abbreviated as “BM”), a complex oxide containing bismuth, potassium, titanium, and iron and having a perovskite structure (x[(BiₓK₁₋ₓ)TiO₃]-(1-x) [BiFeO₃], abbreviated as “BKT-BF”), a composite oxide containing bismuth, iron, barium and titanium and having a perovskite structure ((1-x)[BiFeO₃]-x[BaTIO₃], abbreviated as “BFO-BT”) or a composite oxide added with a metal such as manganese, cobalt, and chromium ((1-x)[Bi(Fe_{1-y}M_{y})O₃]-x[BaTIO₃] (M is Mn, Co or Cr)), or the like.

As illustrated in FIG. 3, the second electrode 80 is a common electrode that is commonly provided for the plurality of pressure chambers 12. The second electrode 80 has a predetermined width in the X-axis direction, and is provided to extend along the arrangement direction of the pressure chambers 12, that is, the Y-axis direction. As illustrated in FIG. 6, the second electrode 80 is an upper electrode provided on the opposite side to the first electrode 60 with the piezoelectric body 70 interposed therebetween, that is, on the upper side of the piezoelectric body 70. As a material of the second electrode 80, similar to the first electrode 60, for example, metals, such as platinum (Pt), iridium (Ir), gold (Au), and titanium (Ti), and conductive materials including conductive metal oxides, such as indium tin oxide abbreviated as ITO, are used. The second electrode 80 may be formed by laminating a plurality of materials such as platinum (Pt), iridium (Ir), gold (Au), and titanium (Ti). In the present embodiment, iridium (Ir) is used as the second electrode 80.

As illustrated in FIG. 6, a wiring portion 85 is provided on the −X direction side rather than one end portion 80b of the second electrode 80 in the −X direction. In FIG. 3 and FIG. 5, the wiring portion 85 is not illustrated. The wiring portion 85 is in the same layer as the second electrode 80, but is electrically discontinuous with the second electrode 80. The wiring portion 85 is formed from one end portion 70b of the piezoelectric body 70 in the −X direction to one end portion 60b of the first electrode 60 in the −X direction in a state where an interval is formed from one end portion 80b of the second electrode 80. The one end portion 60b of the first electrode 60 in the −X direction is drawn out to the outside of one end portion 70b of the piezoelectric body 70. The wiring portion 85 is provided for each piezoelectric element 300, and a plurality of wiring portions 85 are disposed at predetermined intervals along the Y-axis direction. It is preferable that the wiring portion 85 is formed in the same layer as the second electrode 80. As a result, the cost can be reduced by simplifying a manufacturing step of the wiring portion 85. However, the wiring portion 85 may be formed in a layer different from the layer of the second electrode 80.

As illustrated in FIG. 5 and FIG. 6, the first drive wiring 91 is electrically coupled to the first electrode 60 which is an individual electrode, and an extension portion 92a and an extension portion 92b of the second drive wiring 92 are electrically coupled to the second electrode 80 which is a common electrode. The first drive wiring 91 and the second drive wiring 92 function as drive wirings for applying a voltage for driving the piezoelectric body 70 from the wiring substrate 120.

The first drive wiring 91 is individually provided for each first electrode 60. As illustrated in FIG. 6, the first drive wiring 91 is coupled to the vicinity of the one end portion 60b of the first electrode 60 via the wiring portion 85, and is drawn out in the −X direction to reach a top of the vibration plate 50. The first drive wiring 91 is electrically coupled to the one end portion 60b of the first electrode 60 in the −X direction, which is drawn out to the outside of the one end portion 70b of the piezoelectric body 70. The wiring portion 85 may be omitted, and the first drive wiring 91 may be directly coupled to the one end portion 60b of the first electrode 60.

As illustrated in FIG. 3, the second drive wiring 92 extends along the Y-axis direction, bends at both ends in the Y-axis direction, and is drawn out along the X-axis direction. The second drive wiring 92 includes an extension portion 92a extending along the Y-axis direction and an extension portion 92b. As illustrated in FIG. 3 and FIG. 4, the end portions of the first drive wiring 91 and the second drive wiring 92 are extended so as to be exposed to the through hole 32 of the sealing substrate 30, and are electrically coupled to the wiring substrate 120 in the through hole 32.

The materials of the first drive wiring 91 and the second drive wiring 92 are conductive materials. For example, gold (Au), copper (Cu), titanium (Ti), tungsten (W), nickel (Ni), chromium (Cr), platinum (Pt), aluminum (Al), and the like can be used. In the present embodiment, gold (Au) is used for the first drive wiring 91 and the second drive wiring 92. In the present embodiment, the first drive wiring 91 and the second drive wiring 92 are formed by sputtering. The first drive wiring 91 and the second drive wiring 92 are not limited to the sputtering and may be formed by any known film forming technique.

The first drive wiring 91 and the second drive wiring 92 are formed in the same layer in a state of being electrically discontinuous with each other. As a result, the step of forming the first drive wiring 91 and the second drive wiring 92 can be shared, and the manufacturing step can be simplified and the decrease in productivity of the liquid discharge head 510 can be suppressed as compared with the case where the first drive wiring 91 and the second drive wiring 92 are individually formed. Here, the first drive wiring 91 and the second drive wiring 92 may be formed in different layers from each other. The first drive wiring 91 and the second drive wiring 92 may have an adhesion layer that improves adhesion to the first electrode 60, the second electrode 80, or the vibration plate 50.

The wiring substrate 120 is configured with, for example, a flexible printed circuit (FPC). The wiring substrate 120 is formed with a plurality of wirings for coupled to the control section 580 and a power supply circuit (not illustrated). In addition, the wiring substrate 120 may be composed of any flexible substrate, such as Flexible Flat Cable (FFC), instead of FPC. An integrated circuit 121 including a switching element and the like is mounted at the wiring substrate 120. A command signal or the like for driving the piezoelectric element 300 is input to the integrated circuit 121. The integrated circuit 121 controls a timing at which a drive signal for driving the piezoelectric element 300 is supplied to the first electrode 60 based on the command signal.

As illustrated in FIG. 5, the protective layer 82 is formed at a position overlapping the end portion of the second electrode 80 in a plan view of the liquid discharge head 510. In addition, as illustrated in FIG. 6, the protective layer 82 is formed to cover the one end portion 80b of the second electrode 80 on the −X direction side and the surface of the piezoelectric body 70. The thickness of the protective layer 82 is formed to be, for example, approximately 100 nanometers.

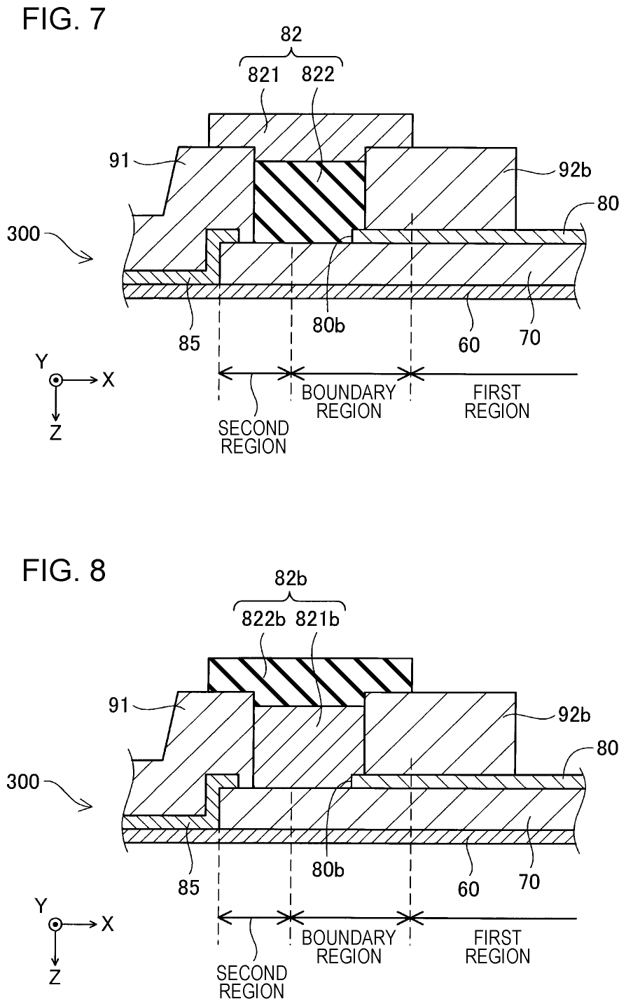

FIG. 7 is an enlarged cross-sectional view of the vicinity of the protective layer 82. In the present specification, as illustrated in FIG. 7, a region where the piezoelectric body 70 and the second electrode 80 overlap in the Z-axis direction, which is the lamination direction, is referred to as a first region, a region where the piezoelectric body 70 is present and the second electrode 80 is not present in the lamination direction is referred to as a second region, and a region which is a boundary between the first region and the second region in the X-axis direction, which is the extending direction, is referred to as a boundary region. The protective layer 82 is provided on the −Z direction side with respect to the piezoelectric body 70 and the second electrode 80 in the boundary region. In addition, the protective layer 82 is provided on the −Z direction side with respect to the piezoelectric body 70 in the second region.

The protective layer 82 includes a first inorganic film 821 and a second inorganic film 822. The second inorganic film 822 is laminated on the −Z direction side of the piezoelectric body 70, and the first inorganic film 821 is laminated on the −Z direction side of the second inorganic film 822. The first inorganic film 821 is made of an inorganic material having the water resistance. In the present embodiment, the first inorganic film 821 is made of aluminum oxide (AlOₓ). The second inorganic film 822 is an inorganic material different from the first inorganic film 821, and is made of an inorganic material having an insulating property. In the present embodiment, the second inorganic film 822 is made of silicon oxide (SiOₓ). The second inorganic film 822 is formed to have a thickness in the lamination direction thicker than the thickness of the first inorganic film 821 in the lamination direction. The first inorganic film 821 and the second inorganic film 822 are formed by a method such as a sputtering method, a chemical vapor deposition method, an atomic layer deposition method, or a vapor deposition method. The first inorganic film 821 may be made of titanium oxide (TiOₓ), tantalum oxide (TaOₓ), hafnium oxide (HfOₓ), or the like instead of aluminum oxide, or may be made of a plurality of these inorganic materials. In addition, the second inorganic film 822 may be made of silicon nitride (SiNₓ) or silicon carbide (SiCₓ) instead of silicon oxide, or may be made of a plurality of these inorganic materials.

According to the liquid discharge head 510 in the first embodiment described above, in the boundary region where the one end portion 80b of the second electrode 80 is located in the extending direction, the protective layer 82 is formed on the −Z direction side, which is the other side in the lamination direction, of the piezoelectric body 70. The protective layer 82 includes a first inorganic film 821 made of an inorganic material and a second inorganic film 822 made of an inorganic material different from the first inorganic film 821. Since the protective layer 82 is made of two films including the first inorganic film 821 and the second inorganic film 822, even when pinholes are formed in one of the films or when foreign substances are contained in one of the films, the piezoelectric body 70 is covered with the other film. Therefore, it is possible to suppress the mixing of the outside air and moisture in the air into the piezoelectric body 70 in the vicinity of the one end portion 80b of the second electrode 80. In addition, compared to a case where the film of any one of the protective layers 82 is made of an organic material, such as polyimide, which easily absorbs moisture, it is possible to suppress the mixing of the moisture into the piezoelectric body 70 in the vicinity of the one end portion 80b of the second electrode 80. As a result, it is possible to reduce the possibility that the burning occurs in the piezoelectric body 70 in the vicinity of the one end portion 80b of the second electrode 80.

In addition, in the present embodiment, the first inorganic film 821 has the water resistance. Therefore, even when a crack is generated in the piezoelectric body 70 in the vicinity of the one end portion 80b of the second electrode 80, it is possible to suppress the mixing of the moisture into the crack. In addition, in the present embodiment, the second inorganic film 822 has an insulating property. Therefore, even when moisture is mixed in the crack generated in the piezoelectric body 70 in the vicinity of the one end portion 80b of the second electrode 80, it is possible to suppress the short circuit between the first electrode 60 and the second electrode 80.

In the present embodiment, the second inorganic film 822 is laminated on the −Z direction side of the piezoelectric body 70, and the first inorganic film 821 is laminated on the −Z direction side of the second inorganic film 822. Since the first inorganic film 821 having the water resistance is provided on the outermost side of the protective layer 82, it is possible to suppress the mixing of the moisture into the second inorganic film 822 and the piezoelectric body 70.

In addition, in the present embodiment, the thickness of the second inorganic film 822 in the lamination direction is thicker than the thickness of the first inorganic film 821 in the lamination direction. As illustrated in FIG. 4, since the sealing substrate 30 is provided on the −Z direction side of the piezoelectric element 300, there is an upper limit to the thickness of the protective layer 82 in the lamination direction. According to the present embodiment, since the thickness of the second inorganic film 822 having an insulating property is thicker than the thickness of the first inorganic film 821 having the water resistance, the insulating property of the protective layer 82 can be enhanced.

In the present embodiment, the protective layer 82 is provided on the −Z direction side of the piezoelectric body 70 in the second region, which is a region in which the piezoelectric body 70 is present and the second electrode 80 is not present in the lamination direction. Therefore, it is possible to suppress the mixing of the moisture from the second region into the piezoelectric body 70.

Further, the liquid discharge device 500 of the present embodiment includes the liquid discharge head 510 and the control section 580 that controls the discharge operation of discharging the liquid from the liquid discharge head 510. Therefore, in the liquid discharge device 500, it is possible to reduce the possibility that the burning occurs in the piezoelectric body 70 in the vicinity of the end portion of the second electrode 80 included in the liquid discharge head 510.

In the present embodiment, the protective layer 82 covers the one end portion 80b of the second electrode 80, and thus it is possible to suppress or prevent peeling from the one end portion 80b of the second electrode 80. Further, since the one end portion 80b is covered, it is possible to suppress the driving of the piezoelectric element 300 in the vicinity of the end portion of the active portion of the piezoelectric element 300.

### B. Second Embodiment

FIG. 8 is an enlarged cross-sectional view of a vicinity of a protective layer 82b according to a second embodiment. The configuration of each portion of the liquid discharge device 500 other than the protective layer 82b according to the second embodiment is the same as in the first embodiment.

In the second embodiment, a first inorganic film 821b is laminated on the −Z direction side of the piezoelectric body 70, and a second inorganic film 822b is laminated on the −Z direction side of the first inorganic film 821b. The second inorganic film 822b is formed to have a thickness in the lamination direction thinner than the thickness of the first inorganic film 821b in the lamination direction. The first inorganic film 821b is made of the same inorganic material as the first inorganic film 821 in the first embodiment, and the second inorganic film 822b is made of the same inorganic material as the second inorganic film 822 in the first embodiment.

According to the liquid discharge head 510 in the second embodiment described above, the first inorganic film 821b is laminated on the −Z direction side of the piezoelectric body 70, and the second inorganic film 822b is laminated on the −Z direction side of the first inorganic film 821b. Since the first inorganic film 821b having the water resistance is provided at a position closer to the piezoelectric body 70 than the second inorganic film 822b having the insulating property, it is possible to further reduce the possibility that moisture is mixed into the piezoelectric body 70.

In the present embodiment, the thickness of the second inorganic film 822b having the insulating property in the lamination direction is thinner than the thickness of the first inorganic film 821b having the water resistance in the lamination direction. As described above, since there is an upper limit to the thickness of the protective layer 82b in the lamination direction, according to the present embodiment, the water resistance of the protective layer 82b can be enhanced.

### C. Third Embodiment

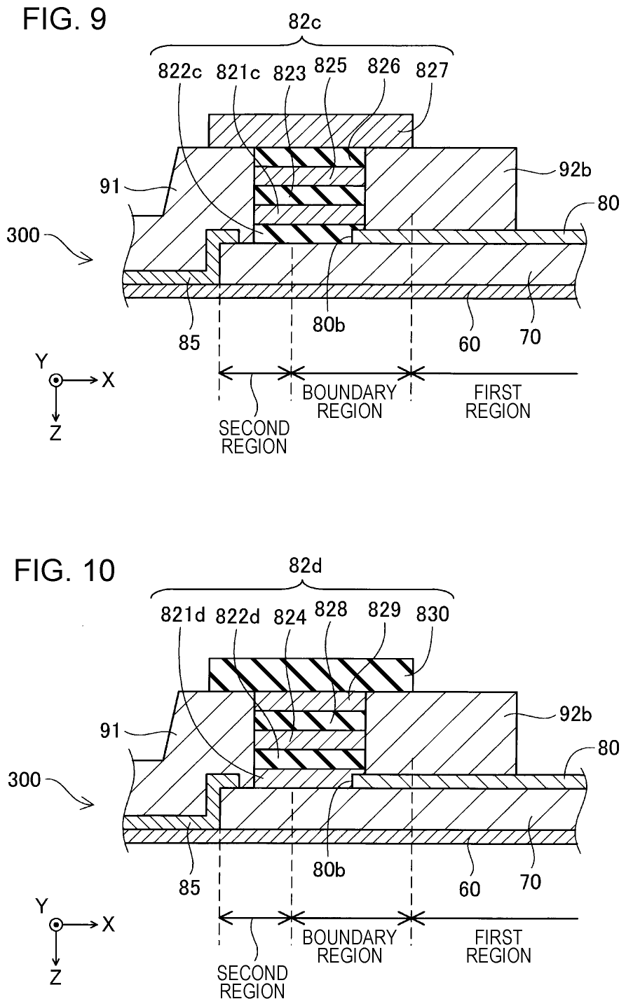

FIG. 9 is an enlarged cross-sectional view of a vicinity of a protective layer 82c according to a third embodiment. The configuration of each portion of the liquid discharge device 500 other than the protective layer 82c in the third embodiment is the same as in the first embodiment.

In the third embodiment, the protective layer 82c includes a first inorganic film 821c, a second inorganic film 822c, a third inorganic film 823, a fifth inorganic film 825, a sixth inorganic film 826, and a seventh inorganic film 827. The second inorganic film 822c is laminated on the −Z direction side of the piezoelectric body 70. The first inorganic film 821c is laminated on the −Z direction side of the second inorganic film 822c. The third inorganic film 823 is laminated on the −Z direction side of the first inorganic film 821c. The fifth inorganic film 825 is laminated on the −Z direction side of the third inorganic film 823. The sixth inorganic film 826 is laminated on the −Z direction side of the fifth inorganic film 825. The seventh inorganic film 827 is laminated on the −Z direction side of the sixth inorganic film 826. The third inorganic film 823 and the sixth inorganic film 826 are made of the same inorganic material as the inorganic material constituting the second inorganic film 822c, and the fifth inorganic film 825 and the seventh inorganic film 827 are made of the same inorganic material as the inorganic material constituting the first inorganic film 821c. Here, the first inorganic film 821c is made of the same inorganic material as the first inorganic film 821 in the first embodiment, and the second inorganic film 822c is made of the same inorganic material as the second inorganic film 822 in the first embodiment. That is, the protective layer 82c is configured by alternately laminating a plurality of films having the water resistance and a plurality of films having the insulating property.

According to the liquid discharge head 510 in the third embodiment described above, the second inorganic film 822c is laminated on the −Z direction side of the piezoelectric body 70, the first inorganic film 821c is laminated on the −Z direction side of the second inorganic film 822c, and the third inorganic film 823 made of the same inorganic material as the second inorganic film 822c is laminated on the −Z direction side of the first inorganic film 821c. The third inorganic film 823 is a film having the same insulating property as the second inorganic film 822c. Therefore, the insulating property of the protective layer 82c can be further enhanced.

In the present embodiment, since the protective layer 82 is configured by alternately laminating a plurality of films having the water resistance and a plurality of films having the insulating property, even when pinholes are present in some of the films or when some of the films contain foreign substances, the possibility that moisture is mixed into the piezoelectric body 70 in the vicinity of the one end portion 80b of the second electrode 80 can be further reduced.

### D. Fourth Embodiment

FIG. 10 is an enlarged cross-sectional view of a vicinity of a protective layer 82d according to the fourth embodiment. The configuration of each portion of the liquid discharge device 500 other than the protective layer 82d according to the fourth embodiment is the same as in the first embodiment.

In the fourth embodiment, the protective layer 82d includes a first inorganic film 821d, a second inorganic film 822d, a fourth inorganic film 824, an eighth inorganic film 828, a ninth inorganic film 829, and a tenth inorganic film 830. The first inorganic film 821d is laminated on the −Z direction side of the piezoelectric body 70. The second inorganic film 822d is laminated on the −Z direction side of the first inorganic film 821d. The fourth inorganic film 824 is laminated on the −Z direction side of the second inorganic film 822d. The eighth inorganic film 828 is laminated on the −Z direction side of the fourth inorganic film 824. The ninth inorganic film 829 is laminated on the −Z direction side of the eighth inorganic film 828. The tenth inorganic film 830 is laminated on the −Z direction side of the ninth inorganic film 829. The fourth inorganic film 824 and the ninth inorganic film 829 are made of the same inorganic material as the inorganic material constituting the first inorganic film 821d, and the eighth inorganic film 828 and the tenth inorganic film 830 are made of the same inorganic material as the inorganic material constituting the second inorganic film 822d. Here, the first inorganic film 821d is made of the same inorganic material as the first inorganic film 821 in the first embodiment, and the second inorganic film 822d is made of the same inorganic material as the second inorganic film 822 in the first embodiment. That is, the protective layer 82d is configured by alternately laminating a plurality of films having the water resistance and a plurality of films having the insulating property.

According to the liquid discharge head 510 in the fourth embodiment described above, the first inorganic film 821d is laminated on the −Z direction side of the piezoelectric body 70, the second inorganic film 822d is laminated on the −Z direction side of the first inorganic film 821d, and the fourth inorganic film 824 made of the same inorganic material as the first inorganic film 821d is laminated on the −Z direction side of the second inorganic film 822d. The fourth inorganic film 824 is a film having the water resistance similar to the first inorganic film 821d. Therefore, the water resistance of the protective layer 82d can be further improved.

In addition, in the present embodiment, since the protective layer 82d is configured by alternately laminating a plurality of films having the water resistance and a plurality of films having the insulating property, even when pinholes are present in some of the films or when some of the films contain foreign substances, it is possible to further reduce the possibility that moisture is mixed into the piezoelectric body 70 in the vicinity of the one end portion 80b of the second electrode 80.

### E. Fifth Embodiment

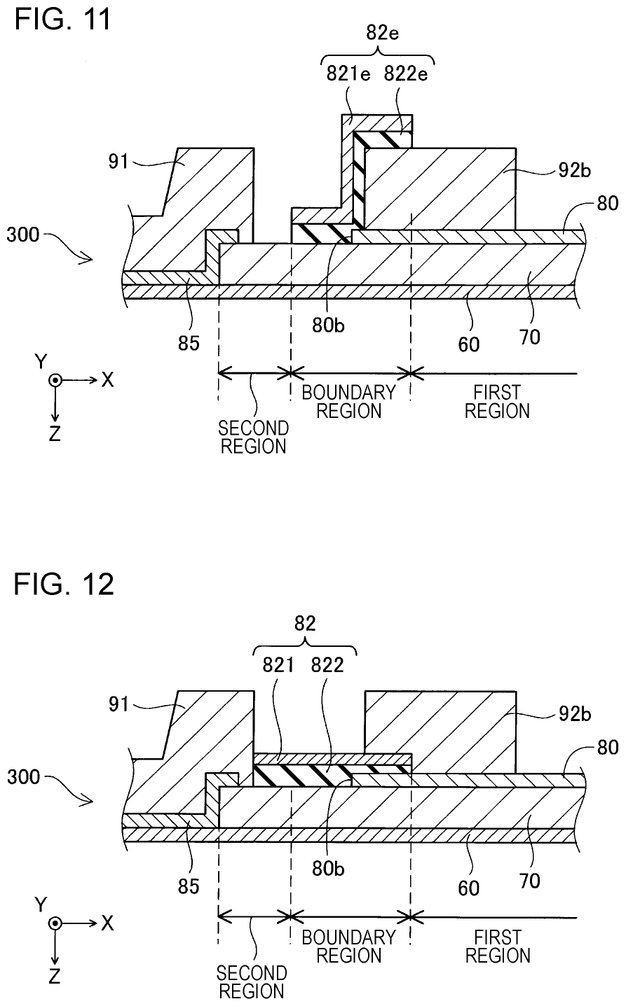

FIG. 11 is an enlarged cross-sectional view of a vicinity of a protective layer 82e according to the fifth embodiment. The configuration of each portion of the liquid discharge device 500 other than the protective layer 82e according to the fifth embodiment is the same as in the first embodiment.

In the fifth embodiment, the protective layer 82e is provided on the −Z direction side of the piezoelectric body 70 in the boundary region where the one end portion 80b of the second electrode 80 is located in the extending direction, and is not provided on the −Z direction side of the piezoelectric body 70 in the second region in which the piezoelectric body 70 is present in the lamination direction and the second electrode 80 is not present. The protective layer 82e is made of a first inorganic film 821e and a second inorganic film 822e. The second inorganic film 822e is laminated on the −Z direction side of the piezoelectric body 70, and the first inorganic film 821e is laminated on the −Z direction side of the second inorganic film 822e. The first inorganic film 821e is made of the same inorganic material as the first inorganic film 821 in the first embodiment, and the second inorganic film 822e is made of the same inorganic material as the second inorganic film 822 in the first embodiment.

According to the liquid discharge head 510 in the fifth embodiment described above, the protective layer 82e is formed on the −Z direction side, which is the other side in the lamination direction, of the piezoelectric body 70 in the boundary region where the one end portion 80b of the second electrode 80 is located in the extending direction. Therefore, it is possible to suppress the mixing of the moisture into the piezoelectric body 70 in the vicinity of the one end portion 80b of the second electrode 80. Further, since the protective layer 82e is not formed on the −Z direction side of the piezoelectric body 70 in the second region, the size of the protective layer 82e in the extending direction can be reduced while suppressing the mixing of moisture into the piezoelectric body 70.

### F. Other Embodiments

(F-1) In the first embodiment, the thickness of the second inorganic film 822 in the lamination direction is thicker than the thickness of the first inorganic film 821 in the lamination direction. On the other hand, in the first embodiment, the thickness of the second inorganic film 822 in the lamination direction may be thinner than the thickness of the first inorganic film 821 in the lamination direction. According to such an aspect, since the thickness of the first inorganic film 821 having the water resistance is thicker than the thickness of the second inorganic film 822 having the insulating property, the water resistance of the protective layer 82 can be enhanced.

(F-2) In the second embodiment, the thickness of the second inorganic film 822b in the lamination direction is thinner than the thickness of the first inorganic film 821b in the lamination direction. On the other hand, in the second embodiment, the thickness of the second inorganic film 822b in the lamination direction may be thicker than the thickness of the first inorganic film 821b in the lamination direction. According to such an aspect, since the thickness of the second inorganic film 822b having the insulating property is thicker than the thickness of the first inorganic film 821b having the water resistance, the insulating property of the protective layer 82b can be enhanced.

(F-3) In the above embodiment, the protective layer 82 is formed on the −Z direction side, which is the other side in the lamination direction, with respect to the extension portion 92b of the second drive wiring 92. On the other hand, as illustrated in FIG. 12, the protective layer 82 may be formed between the second electrode 80 and the second drive wiring 92 in the lamination direction.

(F-4) In the above embodiment, the first inorganic film 821 has the water resistance, and the second inorganic film 822 has the insulating property. On the other hand, the first inorganic film 821 and the second inorganic film 822 may be made of different inorganic materials from each other, and both the first inorganic film 821 and the second inorganic film 822 may have water resistance, or both may have the insulating property.

(F-5) In the third embodiment, the protective layer 82c includes the first inorganic film 821c, the second inorganic film 822c, the third inorganic film 823, the fifth inorganic film 825, the sixth inorganic film 826, and the seventh inorganic film 827. On the other hand, the protective layer 82c may not include the fifth inorganic film 825, the sixth inorganic film 826, and the seventh inorganic film 827.

(F-6) In the fourth embodiment, the protective layer 82d includes the first inorganic film 821d, the second inorganic film 822d, the fourth inorganic film 824, the eighth inorganic film 828, the ninth inorganic film 829, and the tenth inorganic film 830. On the other hand, the protective layer 82d may not include the eighth inorganic film 828, the ninth inorganic film 829, and the tenth inorganic film 830.

(F-7) In the third embodiment and the fourth embodiment, the protective layers 82c and 82d are configured by alternately laminating three films having the water resistance and three films having the insulating property. On the other hand, the protective layers 82c and 82d may be configured by alternately laminating a plurality of films having the water resistance and a plurality of films having the insulating property, and the number of films having the water resistance and the number of films having the insulating property included in the protective layers 82c and 82d are not limited to three.

### G. Other Aspects

The present disclosure is not limited to the above-described embodiments, and can be realized in various aspects without departing from the gist thereof. For example, the present disclosure can also be realized in the following aspects. Technical features in the embodiments corresponding to technical features in respective aspects described below can be appropriately replaced or combined in order to solve some or all of the problems of the present disclosure, or achieve some or all of the effects of the present disclosure. Further, when the technical features are not described as essential in the present specification, the technical features can be appropriately deleted.

(1) According to a first aspect of the present disclosure, there is provided a liquid discharge head. The liquid discharge head includes a piezoelectric body; a pressure chamber substrate provided with a plurality of pressure chambers arranged in an arrangement direction, which is a direction intersecting an extending direction of the pressure chamber, the pressure chamber being configured to apply pressure to a liquid stored inside when the piezoelectric body is driven; a first electrode provided on one side of a lamination direction, which is a direction intersecting the extending direction and the arrangement direction, with respect to the piezoelectric body; a second electrode provided on another side of the lamination direction, which is a side opposite to the one side, with respect to the piezoelectric body; and a protective layer provided on the other side with respect to the piezoelectric body in a boundary region, which is a boundary between a first region and a second region, in the extending direction when the first region is set to a region where the piezoelectric body overlaps the second electrode in the lamination direction and the second region is set to a region where the piezoelectric body is present and the second electrode is not present in the lamination direction, in which the protective layer includes a first inorganic film made of an inorganic material, and a second inorganic film made of an inorganic material different from the first inorganic film, and the first region overlaps the pressure chamber in the lamination direction.

According to such an aspect, it is possible to suppress the mixing of the moisture into the piezoelectric body in the vicinity of the end portion of the second electrode located in the boundary region, and as a result, it is possible to reduce the possibility that the piezoelectric body is burned in the vicinity of the end portion of the second electrode.

(2) In the above-described aspect, the first inorganic film may have water resistance, and the second inorganic film may have an insulating property.

According to such an aspect, it is possible to suppress the mixing of the moisture into the crack generated in the piezoelectric body in the vicinity of the end portion of the second electrode, and to suppress the short circuit between the first electrode and the second electrode when the moisture is mixed in the crack.

(3) In the above-described aspect, the first inorganic film may contain at least one of aluminum oxide, titanium oxide, tantalum oxide, and hafnium oxide.

(4) In the above-described aspect, the second inorganic film may contain at least one of silicon oxide, silicon nitride, and silicon carbide.

(5) In the above aspect, the second inorganic film may be laminated on the other side of the piezoelectric body, and the first inorganic film may be laminated on the other side of the second inorganic film.

According to such an aspect, it is possible to suppress the mixing of the moisture into the second inorganic film and the piezoelectric body.

(6) In the above-described aspect, the second inorganic film may have a thickness thicker than the first inorganic film in the lamination direction.

According to such an aspect, when the thickness of the protective layer in the lamination direction is limited, the insulating property of the protective layer can be enhanced.

(7) In the above-described aspect, the second inorganic film may have a thickness thinner than the first inorganic film in the lamination direction.

According to such an aspect, when the thickness of the protective layer in the lamination direction is limited, the water resistance of the protective layer can be enhanced.

(8) In the above-described aspect, the liquid discharge head may further include a third inorganic film made of the inorganic material constituting the second inorganic film and laminated on the other side of the first inorganic film.

According to such an aspect, the insulating property of the protective layer can be further improved.

(9) In the above aspect, the first inorganic film may be laminated on the other side of the piezoelectric body, and the second inorganic film may be laminated on the other side of the first inorganic film.

According to such an aspect, it is possible to further reduce the possibility that moisture is mixed into the piezoelectric body.

(10) In the above-described aspect, the second inorganic film may have a thickness thinner than the first inorganic film in the lamination direction.

According to such an aspect, when the thickness of the protective layer in the lamination direction is limited, the water resistance of the protective layer can be enhanced.

(11) In the above-described aspect, the second inorganic film may have a thickness thicker than the first inorganic film in the lamination direction.

According to such an aspect, when the thickness of the protective layer in the lamination direction is limited, the insulating property of the protective layer can be enhanced.

(12) In the above-described aspect, the liquid discharge head may further include a fourth inorganic film made of the inorganic material constituting the first inorganic film and laminated on the other side of the second inorganic film.

According to such an aspect, the water resistance of the protective layer can be further improved.

(13) In the above aspect, the protective layer may be provided on the other side of the piezoelectric body in the second region.

According to such an aspect, it is possible to suppress the mixing of the moisture from the second region into the piezoelectric body.

(14) In the above aspect, the protective layer may not be provided on the other side of the piezoelectric body in the second region.

According to such an aspect, the size of the protective layer in the extending direction can be reduced.

(15) According to a second aspect of the present disclosure, there is provided a liquid discharge device. The liquid discharge device includes the liquid discharge head of the first aspect, and a control section that controls a discharge operation of discharging a liquid from the liquid discharge head.

According to the aspect, in the liquid discharge device, it is possible to reduce the possibility that the burning occurs in the piezoelectric body in the vicinity of the end portion of the second electrode included in the liquid discharge head.

The present disclosure can also be realized in various aspects other than the liquid discharge device and the liquid discharge head. For example, it is possible to realize the present disclosure with an aspect of a method for manufacturing a liquid discharge head, a method for manufacturing a liquid discharge device, or the like.

The present disclosure is not limited to the ink jet method, and can be applied to any liquid discharge device that discharges a liquid other than the ink and a liquid discharge head that is used for the liquid discharge device. For example, the present disclosure can be applied to the following various liquid discharge devices and liquid discharge heads thereof.
(1) An image recording device such as a facsimile device.
(2) A color material discharge device used for manufacturing a color filter for an image display device such as a liquid crystal display.
(3) An electrode material discharge device used for forming electrodes of an organic Electro Luminescence (EL) display, a Field Emission Display (FED), or the like.
(4) A liquid discharge device that discharges a liquid containing a bioorganic material used for manufacturing a biochip.
(5) A sample discharge device as a precision pipette.
(6) A lubricating oil discharge device.
(7) A resin liquid discharge device.
(8) A liquid discharge device that discharges lubricating oil with pinpoint to a precision machine such as a watch or a camera.
(9) A liquid discharge device that discharges a transparent resin liquid, such as an ultraviolet curable resin liquid, onto a substrate in order to form a micro hemispherical lens (optical lens) or the like used for an optical communication element or the like.
(10) A liquid discharge device that discharges an acidic or alkaline etching liquid for etching a substrate or the like.
(11) A liquid discharge device including a liquid consumption head that discharges any other minute amount of droplets.

Further, the “liquid” may be any material that can be consumed by the liquid discharge device. For example, the “liquid” may be a material in a state when a substance is liquefied, and the “liquid” includes a liquid state material with high or low viscosity and a liquid state material, such as a sol, gel water, other inorganic solvent, organic solvent, solution, liquid resin, and liquid metal (metal melt). Further, the “liquid” includes not only a liquid as a state of a substance but also a liquid in which particles of a functional material made of a solid substance, such as a pigment or a metal particle, are dissolved, dispersed, or mixed in a solvent. Further, the following is mentioned as a typical example of a liquid.
(1) Adhesive main agent and curing agent.
(2) Paint-based paints and diluents, clear paints and diluents.
(3) Main solvent and diluting solvent containing cells of ink for cells.
(4) Metallic leaf pigment dispersion liquid and diluting solvent of ink (metallic ink) that develops metallic luster.
(5) Gasoline/diesel and biofuel for vehicle fuel.
(6) Main ingredients and protective ingredients of medicine.
(7) Light Emitting Diode (LED) fluorescent material and encapsulant.

What is claimed is:

1. A liquid discharge head comprising:
a piezoelectric body;
a pressure chamber substrate provided with a plurality of pressure chambers arranged in an arrangement direction, which is a direction intersecting an extending direction of the pressure chamber, the pressure chamber being configured to apply pressure to a liquid stored inside when the piezoelectric body is driven;
a first electrode provided on one side of a lamination direction, which is a direction intersecting the extending direction and the arrangement direction, with respect to the piezoelectric body;
a second electrode provided on another side of the lamination direction, which is a side opposite to the one side, with respect to the piezoelectric body; and
a protective layer provided on the other side with respect to the piezoelectric body in a boundary region, which is a boundary between a first region and a second region, in the extending direction when the first region is set to a region where the piezoelectric body overlaps the second electrode in the lamination direction and the second region is set to a region where the piezoelectric body is present and the second electrode is not present in the lamination direction, wherein
the protective layer includes
a first inorganic film made of an inorganic material, and
a second inorganic film made of an inorganic material different from the first inorganic film, and
the first region overlaps the pressure chamber in the lamination direction.

2. The liquid discharge head according to claim 1, wherein
the first inorganic film has water resistance, and
the second inorganic film has an insulating property.

3. The liquid discharge head according to claim 2, wherein
the first inorganic film contains at least one of aluminum oxide, titanium oxide, tantalum oxide, and hafnium oxide.

4. The liquid discharge head according to claim 2, wherein
the second inorganic film contains at least one of silicon oxide, silicon nitride, and silicon carbide.

5. The liquid discharge head according to claim 2, wherein
the second inorganic film is laminated on the other side of the piezoelectric body, and
the first inorganic film is laminated on the other side of the second inorganic film.

6. The liquid discharge head according to claim 5, wherein
the second inorganic film has a thickness thicker than the first inorganic film in the lamination direction.

7. The liquid discharge head according to claim 5, wherein
the second inorganic film has a thickness thinner than the first inorganic film in the lamination direction.

8. The liquid discharge head according to claim 5, further comprising:
a third inorganic film made of the inorganic material constituting the second inorganic film and laminated on the other side of the first inorganic film.

9. The liquid discharge head according to claim 2, wherein
the first inorganic film is laminated on the other side of the piezoelectric body, and
the second inorganic film is laminated on the other side of the first inorganic film.

10. The liquid discharge head according to claim 9, wherein
the second inorganic film has a thickness thinner than the first inorganic film in the lamination direction.

11. The liquid discharge head according to claim 9, wherein
the second inorganic film has a thickness thicker than the first inorganic film in the lamination direction.

12. The liquid discharge head according to claim 9, further comprising:
a fourth inorganic film made of the inorganic material constituting the first inorganic film, and laminated on the other side of the second inorganic film.

13. The liquid discharge head according to claim 1, wherein
the protective layer is provided on the other side of the piezoelectric body in the second region.

14. The liquid discharge head according to claim 1, wherein
the protective layer is not provided on the other side of the piezoelectric body in the second region.

15. A liquid discharge device comprising:
the liquid discharge head according to claim 1; and
a control section that controls a discharge operation of discharging a liquid from the liquid discharge head.
